(19) United States
(12) Patent Application Publication
(10) Pub. No.: US 2013/0118552 A1
(43) Pub. Date: May 16, 2013

(54) THIN-FILM SOLAR CELL

(71) Applicant: Swinburne University of Technology, Hawthorn VIC (AU)

(72) Inventors: Min Gu, Doncaster (AU); Baohua Jia, Mont Albert North (AU); Xi Chen, Surrey Hills (AU); Jhantu K. Saha, Clayton (AU)

(73) Assignee: Swinburne University of Technology, Hawthorn VIC (AU)

(21) Appl. No.: 13/677,450

(22) Filed: Nov. 15, 2012

(30) Foreign Application Priority Data
Nov. 15, 2011 (AU) 2011904769

(51) Int. Cl. H01L 31/0232; H01L 31/18; H01L 31/052

(52) U.S. Cl. CPC H01L 31/02327; H01L 31/0527; H01L 31/18
USPC 136/246; 136/256; 136/252; 438/71

(57) ABSTRACT

A thin-film solar cell product, including:
a thin film semiconductor having one or more solar cells formed therein, the solar cells having a front surface for receiving incident sunlight, and a rear surface;
at least one reflective layer to reflect light that has passed through the thin film semiconductor without having been absorbed therein; and
a scattering layer including broadband scattering particles configured to scatter light incident upon the scattering layer to increase the absorption of the light in the solar cells.

### RELATED APPLICATIONS

This specification is associated with Australian Provisional Patent Application No. 2011904769 the originally filed specification of which is hereby incorporated herein by reference.

### FIELD

The present invention relates to thin-film solar cells, e.g., including plasmonic nanoparticles.

### BACKGROUND

Thin-film solar cells (SCs) can be a cheaper alternative to bulk crystalline solar cells; however, the significantly reduced thickness of the photovoltaic (PV) layers in a thin-film solar cell leads to reduced sunlight absorption and a lower energy conversion efficiency. Incident sun light (which is also referred to as solar radiation) normally passes directly through the thin film in a direction very close to perpendicular to the film, and thus the incident light has a short interaction length.

One method to improve the efficiency of thin-film solar cells may be to improve light trapping in the cells. It may be possible to use plasmonic structures (which are also referred to as plasmonic nanostructures) to strongly scatter the incident light through large angles; however, previously proposed plasmonic structures require regularly patterned particle arrays or gratings with rigorous geometric precision. Such patterns rely on sophisticated and expensive semiconductor lithography equipment, and thus are less attractive for industrial in-line mass production of thin-film solar cells.

It is desired to address or ameliorate one or more disadvantages or limitations associated with the prior art, or to at least provide a useful alternative.

### SUMMARY

In accordance with the present invention, there is provided a thin-film solar cell product, including:
a thin film semiconductor having one or more solar cells formed therein, the solar cells having a front surface for receiving incident sunlight, and a rear surface;
at least one reflective layer to reflect light that has passed through the thin film semiconductor without having been absorbed therein; and
a scattering layer including broadband scattering particles configured to scatter light incident upon the scattering layer to increase the absorption of the light in the solar cells.

The present invention also provides a method of manufacturing a thin film solar cell product, including forming a scattering layer having broadband scattering particles therein, the broadband scattering particles being configured to scatter light incident upon the scattering layer to increase the absorption of the light in one or more solar cells of the thin film solar cell product.

The present invention also provides a solar cell product including a photovoltaic layer and nanoparticles synthesised using a wet chemical method and configured to scatter sunlight incident upon the nanoparticles to increase the absorption of light in the photovoltaic layer.

In embodiments, the broadband scattering particles can be rough surfaced particles.

In embodiments, the particles each include:
a central core; and
a plurality of truncated sub-particles on the core.

In embodiments, the cell includes a dielectric material around the particles.

In embodiments, the cell includes a dielectric layer of the dielectric material.

In embodiments, the cell includes at least one photovoltaic (PV) apparatus configured to receive the sun light.

In embodiments, the particles scatter a portion of the sun light which is transmitted through the PV apparatus of the solar cell.

In embodiments: the PV apparatus includes at least one PV layer; the PV layer includes a PV film; and the PV film is supported by a substrate.

In embodiments, the method includes the steps of:
forming at least one photovoltaic (PV) apparatus on a substrate; and
providing the particles in a dielectric material to receive a portion of the sun light which is transmitted through the PV apparatus.

In embodiments, the method includes the step of providing the particles in a dielectric layer of the dielectric material.

In embodiments, the method includes the step of depositing the particles between sub-layers of the dielectric layer.

In embodiments, the method includes the step of mixing a weak reductant with a concentrated metal ion solution to form the particles by anisotropic growth.

### BRIEF DESCRIPTION OF THE DRAWINGS

Preferred embodiments of the present invention are hereinafter further described, by way of example only, with reference to the accompanying drawings, in which:

FIG. 1A is a schematic diagram of a solar cell including broadband scattering particles for scattering a plurality of bands of light;

FIG. 1B is a flow chart of a method of manufacturing the solar cell;

FIG. 2(c) is a diagram of one of the particles in the form of a nucleated nanoparticle;

FIG. 2(d) is a graph of a calculated scattering pattern for an example nucleated nanoparticle of 200 nanometers (nm) diameter;

FIG. 3 is a UV-visible spectrum of absorbance of an aqueous suspension with different diameters of nanoparticles;

FIGS. 4(a) to 4(d) are schematic diagrams of the solar cell in different stages of its manufacture;

FIG. 5 is a graph showing a relationship between JSC enhancement and nanoparticle size in example solar cells with different coverage densities varying from 5% to 20%;

FIG. 6 is graph of the External Quantum Efficiency (EQE) for an example solar cell without nanoparticles (broken line) compared to a solar cell with 200-nm nucleated silver nanoparticles at 10% surface coverage (solid line); the inset in FIG. 6 is a graph showing absorption enhancement of the solar cell with the broadband nanoparticles at different wavelengths; and

FIG. 7 is a graph of a J-V characteristic for an example solar cell without broadband nanoparticles (broken line) compared to an example solar cell with 200-nm broadband nanoparticles at 10% coverage density (solid line).

### DETAILED DESCRIPTION

### Solar Cell 100

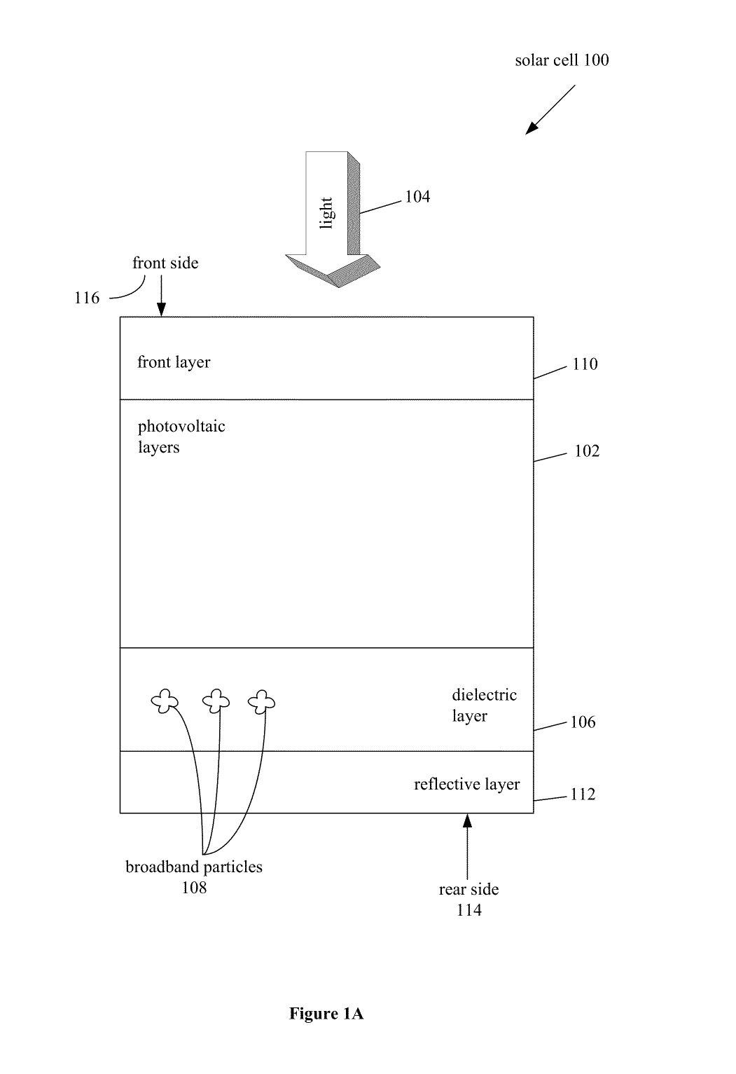

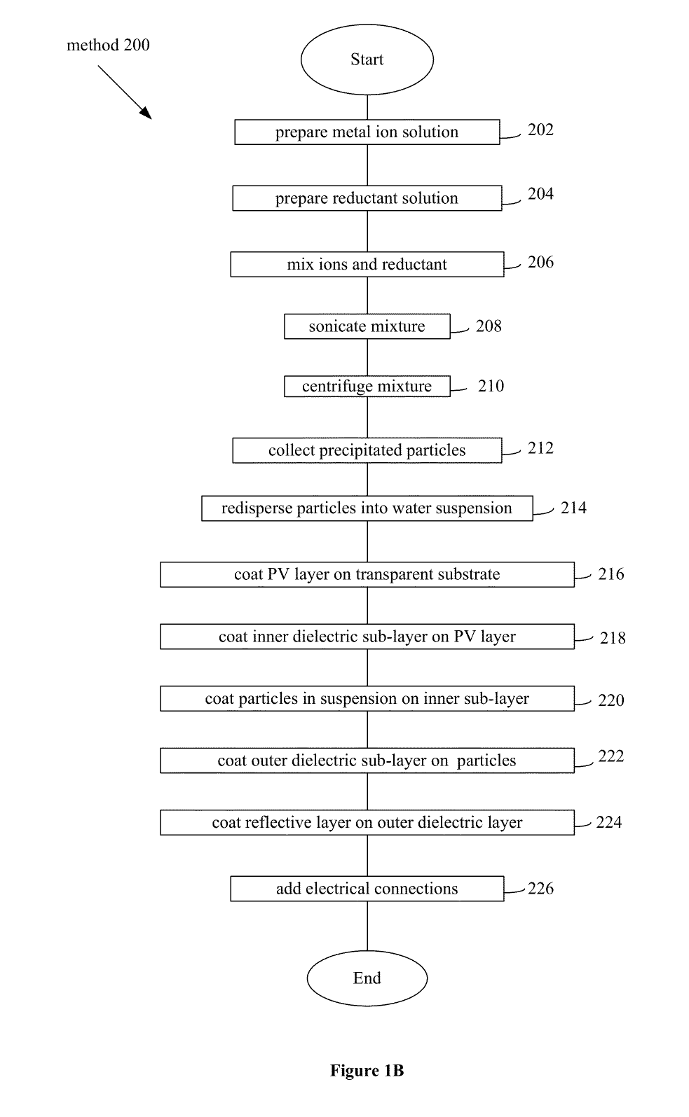

As shown in FIG. 1A, a thin-film solar cell 100 includes a photovoltaic (PV) apparatus formed by a plurality of PV layers 102 for receiving sun light 104 incident perpendicular to the PV layers 102. The cell 100 includes a dielectric layer 106, under and adjacent to the PV layers 102, for receiving a portion of the incident sun light 104 which is transmitted through the PV layers 102. The dielectric layer 106 includes a plurality of broadband scattering particles 108 (which are also referred to as nanoparticles) in a dielectric material of the dielectric layer 106. The particles 108 are configured to scatter a plurality of bands of the transmitted light into different directions (through large angles) to redirect the transmitted light away from the incident direction (which is perpendicular or normal to the PV layers 102). The scattering of the incident light through a large angle directs it at least partially along the thin films of the PV layers 102; thus the interaction length can be increased without increasing the thickness of the films, and the light trapping of the solar cell 100 is improved.

The particles 108 are integrated inside the dielectric layer 106 at the rear side of the cell 100, rather than the front side 116, to avoid direct light shadowing loss by the particles 108.

The PV layers 102 is formed of one or more photovoltaic films on a substrate. The substrate can be a transparent front layer 110 of the cell 100, through which the sun light 104 is transmitted to the PV layers 102. The PV layers 102 can be a silicon layer formed of amorphous silicon.

The cell 100 includes a reflective back layer 112 for reflecting any light transmitted from the PV layers 102 through the dielectric layer 106 back into the dielectric layer 106, and thus into the PV layers 102. Thus, the incident light 104 is not lost from the rear side 114 of the cell 100, but is reflected by the reflective layer 112 to pass into the PV layers 102 for a second time. Thin-film solar cells benefit from a reflection layer because the PV layers 102 is too thin to absorb all of the incident light 104 in one pass.

The particles 108 scatter light from the PV layers 102 and light from the reflective layer 112 through large angles, thus redirecting light from the incident direction (normal to the plane of the PV layers 102) into directions closer to the plane of the PV layers 102. The scattered light thus travels further in the PV layers 102 than it would if it simply passed directly through the PV layers 102 twice in a perpendicular direction (i.e., once in the incident direction, and once on reflection by the reflective layer 112).

As shown in FIG. 2(c), the particles 108 can each include: a central core; and truncated sub-particles on the core. The particles 108 can be referred to as nucleated nanoparticles because they are formed of a main core “nucleus particle” covered in sub-particles. The dimensions of the particles 108 can be tailored to scatter light over a plurality of bands of optical light, in contrast to spherical particles which scatter light over single or narrow bands only.

The geometry of the particles 108 is based on large nanoparticles combined with small particle nucleation to effectively scatter light in a broad spectrum range with large oblique angles, while minimizing detrimental particle absorption. The particles 108 exhibit plasmonic effects under solar radiation, and can be formed of metals such as silver, gold or aluminium, etc. The particles 108 are formed by a wet chemical synthesis method, which can be simple and low-cost, and readily to be scaled up for full size solar cell integration in mass manufacturing. The morphologies of the particles 108 can be controlled by using different reactants and adjusting their concentrations. The particles 108 can be silver nanoparticles which can have a relative scattering efficiency higher than that of other noble metals in the visible range.

The particles 108 may provide surface plasmon modes (thus improving the light absorption within the absorbing layer). The nucleated particles 108 can scatter light in a broadband wavelength range to realize pronounced absorption enhancement in the PV layers 102.

To enhance the light absorption in the PV layers 102, the particles 102 are configured to maximally scatter light at large oblique angles with negligible particle absorption. According to the Mie theory, the scattering and the absorption cross-sections are determined by the nanoparticle size. For example smaller nanoparticles have small scattering/absorption ratio but larger scattering angle, while larger nanoparticles possess dominant scattering but limited scattering angles. The broadband particles 108, as shown in FIG. 2(c), combine properties of the large particles and small particles. Each particle 108 has a large core, which provides a large scattering coefficient in the longer wavelength region due to the excitation of the dipolar and quadrupolar plasmonic modes, covered evenly with half truncated small particles (e.g., ⅕ in size of the large particle), which provide large-angle scatterers for shorter wavelength light. The particles 108 scatter strongly in a broad wavelength range within a large oblique angle, as shown in FIG. 2(d).

### Method 200

In a method 200 of manufacturing the solar cell 100, the particles 108 are synthesised using a wet chemical method which provides self-assembly of the particles 108. As shown in FIG. 1B, the method 200 includes the steps of:
preparing a concentrated metal ion solution (step 202);
preparing a weak reductant solution (step 204);
mixing the ion solution and the reductant solution to form the particles 108 by anisotropic growth along certain crystalline directions (step 206);
sonicating the mixture (step 208);
centrifuging the sonicated mixture (step 210);
collecting the particles 108 as precipitate from the centrifuged mixture (step 212);
redispersing the particles 108 into a suspension, e.g., a water suspension (step 214);
forming the PV layers 102 by coating it onto the substrate (e.g., the conductive transparent front layer 110), e.g., by coating one or more PV films onto the substrate (step 216);
forming a portion of the dielectric layer 106 by coating an inner dielectric sub-layer (of the dielectric layer 106) onto the PV layers 102 (step 218);
providing the particles 108 onto the inner sub-layer by depositing them from the suspension (step 220);
forming another portion of the dielectric layer 106 by coating an outer dielectric sub-layer (of the dielectric layer 106) onto the particles 108 (step 222);
coating the reflective layer 112 on the dielectric layer 106 (step 224); and
adding electrical connections to form the operational solar cell 100.

The wet chemical method for forming the particles 108 can be simple and relatively inexpensive, while still allowing control of the nanoparticle size, shape and particle patterning. The method 200 also allows from control of the coverage density of the particles 108 in the dielectric layer 106, e.g., to densities less than 30%.

Arbitrary coverage densities of the particles 108 on the solar cell 100 can be realized by tuning the concentration of the particles 108 in the suspension.

After integrating the particles 108 (with broadband optical response) inside the dielectric layer 106 at the rear side of the cell 100 with a pre-designed coverage density, the following properties can be observed in the solar cells: consistent absorption, short-circuit photocurrent density (Jsc) and energy conversion efficiency (η) enhancements. For example, 200 nm nucleated silver nanoparticles at a 10% coverage density gives maximum Jsc and η enhancements of 14.26% and 23%, respectively. The highest efficiency achieved can be 8.1% among the measured plasmonic solar cells.

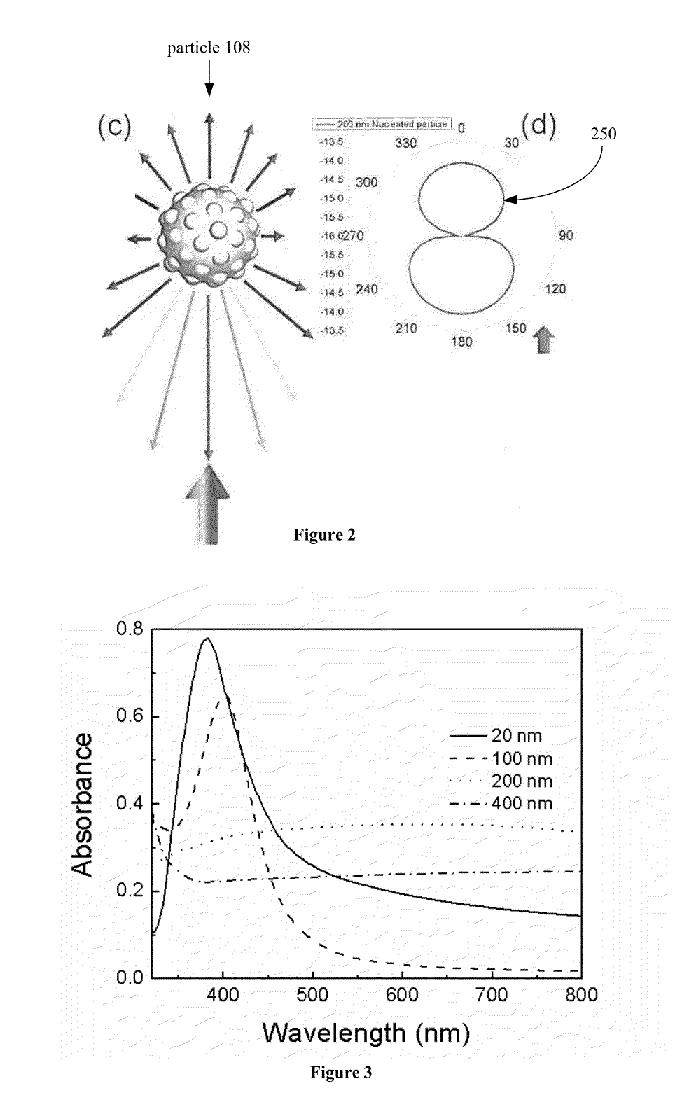

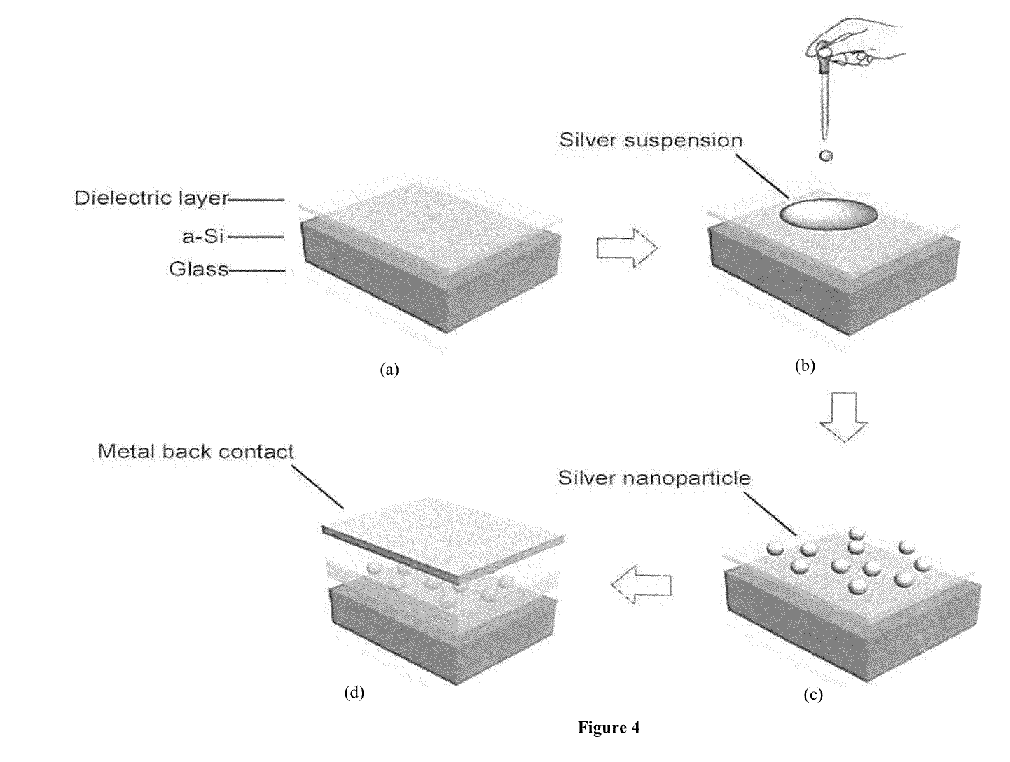

Conventional silver nanoparticle synthesis based on the reduction method can routinely produce nanoparticles ranging from 5 to 100 nm; however, these particles are isotropic during growth due to the use of a strong reductant, e.g., sodium borohydride (NaBH₄). Therefore the particles exhibit almost a perfect spherical shape with small size deviations (<10%) and distinct plasmonic resonance peaks as shown in FIG. 3 (20 nm and 100 nm). To form the controlled nucleated particles 108, e.g., with large sizes (>150 nm), a weaker reductant (e.g., ascorbic acid) and an ion-abundant environment are used (e.g., the Ag⁺ ions), which lead to the particle formation by continuous metal supply and anisotropic growth along certain crystalline directions (as shown below in the Examples).

The tailored particles 108 can be integrated at the rear side of the solar cell 100—before the fabrication of the reflective layer 112 (e.g., a silver back reflector)—with different coverage densities (e.g., less than 30%).

Before the integration of the particles 108, the solar cell samples (e.g., 2 cm²) can subjected to an exposure (e.g., for 5 mins) to ethanol solution under sonication. The particles 108 can be embedded inside the dielectric layer 106 (e.g., including ZnO:Al) at the rear side 114 of the solar cell 100 by the deposition of the suspension. The thickness (e.g., 20 nm) of the inner dielectric sub-layer between the particles 108 and the PV layers 102 can be selected to maximize near-field coupling and avoid potential recombination of the particles 108 into the PV layers 102.

The method 200 can include selecting an preferred size (or diameter) for the particles 108. Selecting the preferred size can include determining a size with a sufficient absorption-to-scattering ratio to substantially scatter the sun light 104, while not allowing excitement of higher-order plasmonic modes (which have a lower scattering-to-absorption ratio than the dipolar and quadrupolar modes). For example, a selected size for the particles 108 can be from 150 to 250 nm, or about 200 nm.

The method 200 can include selecting a preferred particle coverage density, e.g., 10% surface coverage.

### Example 1

An example solar cell with 200-nm nucleated silver nanoparticles at 10% coverage density demonstrated a broadband absorption enhancement and superior performance, including a 14.3% enhancement in the short-circuit photocurrent density and a 23% enhancement in the energy conversion efficiency, compared with the randomly textured reference cells without nanoparticles. The measured efficiency was as high as 8.1%. The significant enhancement was attributable to the broadband light scattering arising from the integration of the tailored nucleated silver nanoparticles.

### Example 2

In a simulated example, the finite-difference time-domain (FDTD) method was employed to calculate the scattering pattern of a 200-nm large nanoparticle covered with 40-nm half-truncated small particles. As shown in FIG. 2(d), the simulated nucleated nanoparticle presented a dramatically different scattering pattern 250 to that of a smooth particle of the same size (200 nm). The scattering pattern 250 is similar to those of 20-nm and 100-nm spherical particles, confirming that large oblique angle has been achieved with this model. On the other hand, the scattering strength of the simulated particle was on the same order of a 200-nm smooth particle, with a scattering coefficient one order of magnitude higher than the absorption coefficient. The simulation result confirmed the feasibility of using the nucleated large particles 108 to achieve large angle broadband scattering.

### Example 3

Example nucleated nanoparticles sizes of 200±10 nm and 400±10 nm exhibited large surface roughness, similar to truncated small particles. The size of the small sub-particles on the surfaces of the 200-nm and 400-nm nucleated particles were approximately 40-50 nm and 80-90 nm, respectively, and were controlled by the growth conditions. Unlike example spherical nanoparticles, which possessed only one distinct plasmonic resonance peak, the 200- and 400-nm nucleated silver nanoparticles produced enhanced broadband absorption features (due to the combined plasmonic effects from both the large core particles and the small surface particles).

### Example 4

In an experimental example, the influence of silver nanoparticles on the performances of solar cells was tested through the relationship between Jsc, a parameter directly related to the light trapping effect of solar cells, and the sizes of the nucleated silver nanoparticles under different coverage densities. The silver nanoparticle integrated solar cells were characterised using a spectrometer (Perkin Elmer, Lambda 1050) to measure the UV-visible spectra. The reflectance (R) and transmittance (T) of the solar cells with and without silver nanoparticle integration were measured with an integrating sphere and the absorption (A) was calculated by A=100%−R−T.

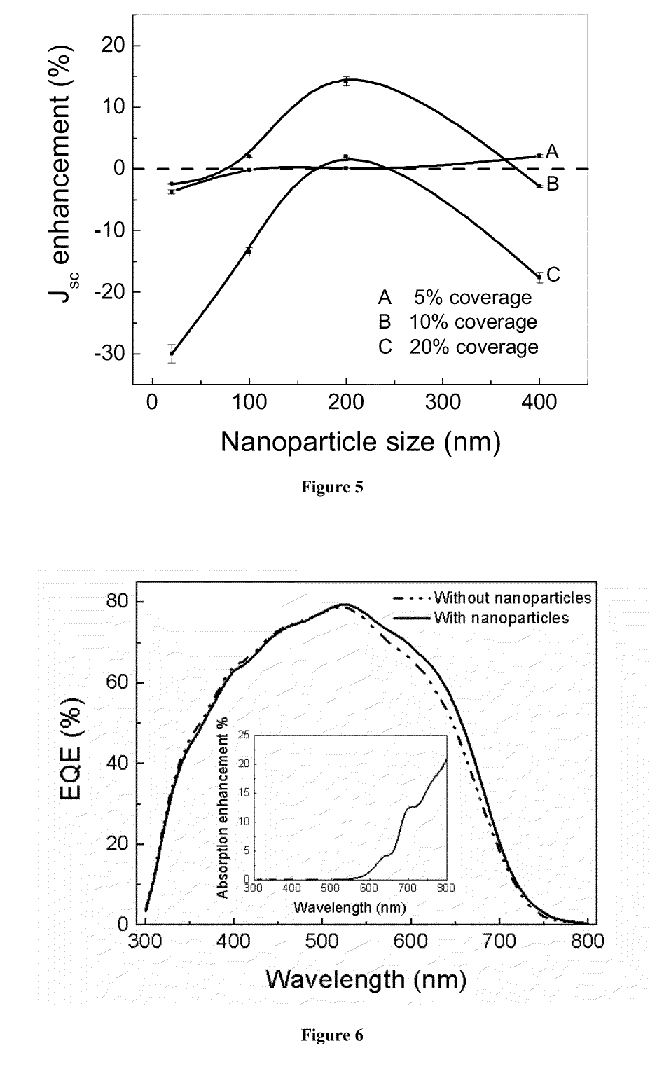

As shown in FIG. 5, for nucleated particle sizes ranging from 20 to 200 nm, larger particles exhibited a higher Jsc enhancement than the smaller ones for all the coverage densities (as predicated by Mie theory).

When example 20-nm nucleated silver nanoparticles were integrated into example thin-film amorphous silicon solar cells, parasitic absorption in the silver nanoparticles dominated because smaller nanoparticles have larger absorption cross-sections than their scattering cross-sections (in the visible wavelength range), which does not lead to a substantial enhancement of the absorbance in the amorphous silicon layer. Consequently the integration of 20-nm silver nanoparticles decreased the Jsc value significantly as shown in FIG. 5.

For the 200-nm nucleated nanoparticles, the Jsc was enhanced for all three coverage densities. The largest Jsc enhancement of 14.3% was achieved at the 10% coverage. The observed pronounced enhancement in Jsc can be due to the increased optical path length in the PV layers 102 resulting from the broadband scattering from the nucleated nanoparticles 108 of the incident light into wider distribution angles.

The example cells integrated with 400-nm nucleated nanoparticles did not show the largest Jsc enhancement. This can be because the large particle size leads to excitation of multiple higher-order plasmonic modes (which have smaller scattering-to-absorption ratio than the dipolar and quadrupolar modes, and thus provide less useful Jsc enhancement), or due to contact loss between the larger embedded particles and the PV layers 102 or the reflective layer 112

As shown in FIG. 5, for example nanoparticle sizes ranging from 20 to 200 nm, 10% surface coverage provided the best photovoltaic properties of the solar cells among all the three coverage densities used in the experiment. This was consistent with the FDTD simulation results. The 5% coverage was insufficient to cause significant impact to Jsc. In contrast, the 20% surface coverage leads to substantial changes in Jsc. When the nanoparticle size was 20 nm, the reduction in Jsc was almost 30% due to the massive particle absorption.

In wavelength dependent absorption and external quantum efficiency (EQE) measurements, as shown in FIG. 6, the photovoltaic performances of the solar cells were characterized by current density-voltage (J-V) measurements under a simulated AM1.5 spectrum (Oriel-Sol 3A-94023) and the EQE measurements (PV Measurement QEX10). As shown in the inset of FIG. 6, the example broadband absorption enhancement was up to 22% at the long wavelength range between 530 and 800 nm due to the integration of the 200-nm nucleated silver nanoparticles compared with a randomly textured reference cells without nanoparticles. As shown in FIG. 6, the EQE measurement also showed broadband enhancement for light wavelengths between 530 and 800 nm. In contrast, the absorption and quantum efficiency below 530 nm were almost unaffected because of the adequate absorption of the short wavelength light by the example PV layers 102.

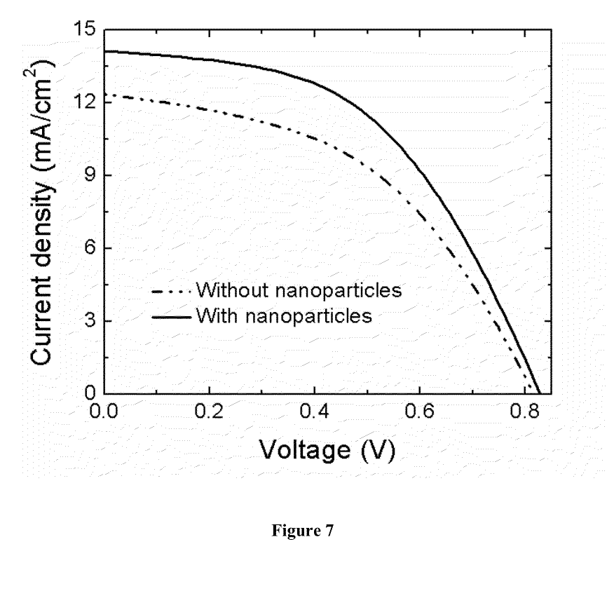

The significant enhancement in Jsc led to the overall efficiency enhancement of 23%, as shown in FIG. 7, in which the J-V curves of solar cells with and without the integration of 200 nm nucleated silver nanoparticles with the 10% coverage density are shown. After the nanoparticle integration, the maximum achieved energy conversion efficiency was 8.1% among all the cells.

The enhancement of the overall efficiency is larger than that of Jsc due to a contribution from an enhanced fill factor (FF) of 6.02%. (In these examples, a FF enhancement was consistently observed for high coverage densities, e.g., about 10% to 20%. In particular in the case of the 20% coverage with 200-nm nucleated particles, the FF enhancement was almost 8%. The enhanced FF can be due to the reduced contact resistivity of the dielectric layer 106 when it includes the particle 108 at sufficiently high coverage densities.

### Example 5

In an example method, to synthesise 20-nm Ag nanoparticles, 5 ml water solution of 0.25 mM AgNO3 and 0.25 mM sodium citrate were added into de-ionised water. Next, the suspension was subjected to sonication. During the sonication for 30 s, 0.15 ml 10 mM freshly prepared NaBH4 was injected quickly at the room temperature. The solution was centrifuged at 10000 rpm for 10 mins, and then the supernatant was removed and the precipitate, containing Ag nanoparticles, was redispersed in de-ionised water.

In an example method, to synthesise 100-nm Ag nanoparticles, 5 ml water solution of 5 mM AgNO3 and 5 mM sodium citrate were added into de-ionised water. Next, the suspension was subjected to sonication. During the sonication for 30 s, 0.6 ml 50 mM freshly prepared NaBH4 was injected quickly at the room temperature. The solution was centrifuged at 5000 rpm for 10 mins, and then the supernatant was removed and the precipitate, containing Ag nanoparticles, was redispersed in de-ionised water.

In an example method, to synthesise 200-nm Ag nanoparticles, 5 ml of solution containing polyvinyl alcohol (15 mg) and ascorbic acid (0.1 mmol) was prepared. Then, 0.5 ml of 0.2 M AgNO3 was added drop wise with shaking The solution was centrifuged at 3000 rpm for 5 mins, and then the supernatant was removed and the precipitate, containing Ag nanoparticles, was redispersed in de-ionised water.

In an example method, to synthesise 400-nm Ag nanoparticles, 5 ml of solution containing polyvinyl alcohol (5 mg) and ascorbic acid (0.1 mmol) was prepared. Then, 0.5 ml of 0.2 M AgNO3 was added drop wise with shaking. The solution was centrifuged at 3000 rpm for 5 mins, and then the supernatant was removed and the precipitate, containing Ag nanoparticles, was redispersed in de-ionised water.

### Interpretation

Many modifications will be apparent to those skilled in the art without departing from the scope of the present invention.

The reference in this specification to any prior publication (or information derived from it), or to any matter which is known, is not, and should not be taken as an acknowledgment or admission or any form of suggestion that the prior publication (or information derived from it) or known matter forms part of the common general knowledge in the field of endeavour to which this specification relates.

1. A thin-film solar cell product, including:
a thin film semiconductor having one or more solar cells formed therein, the solar cells having a front surface for receiving incident sunlight, and a rear surface;
at least one reflective layer to reflect light that has passed through the thin film semiconductor without having been absorbed therein; and
a scattering layer including broadband scattering particles configured to scatter light incident upon the scattering layer to increase the absorption of the light in the solar cells.

2. The solar cell product of claim 1, wherein the scattering layer is between the thin film semiconductor and the reflective layer.

3. The solar cell product of claim 1, wherein the particles each includes:
a central core; and
a plurality of truncated sub-particles on the core.

4. The solar cell product of claim 1, wherein the scattering layer includes a dielectric material, the broadband scattering particles being embedded within the dielectric material.

5. The solar cell product of claim 1, wherein the broadband scattering particles scatter a portion of the light transmitted through the thin film semiconductor.

6. The solar cell product of claim 1, including a substrate to support the thin film semiconductor.

7. A method of manufacturing a thin film solar cell product, including forming a scattering layer having broadband scattering particles therein, the broadband scattering particles being configured to scatter light incident upon the scattering layer to increase the absorption of the light in one or more solar cells of the thin film solar cell product.

8. The method of claim 7, wherein the scattering layer is formed between a thin film semiconductor and a reflective layer so that the scattering layer receives a portion of the sunlight that is transmitted through the thin film semiconductor.

9. The method of claim 7, wherein the scattering layer includes a dielectric material, the broadband scattering particles being embedded within the dielectric material.

10. The method of claim 9, wherein the scattering layer includes at least two layers of the dielectric material, the particles being disposed between said layers.

11. The method of claim 7, including a step of mixing a weak reductant with a concentrated metal ion solution to form the particles by anisotropic growth.

12. The method of claim 7, wherein the particles are rough-surfaced particles.

13. A solar cell product including a photovoltaic layer and nanoparticles synthesised using a wet chemical method and configured to scatter sunlight incident upon the nanoparticles to increase the absorption of light in the photovoltaic layer.

14. The solar cell product of claim 13, wherein the nanoparticles are synthesised to scatter a plurality of bands of sunlight.

15. The solar cell product of claim 13, wherein the nanoparticles include central bodies with attached subparticles thereto.

16. The solar cell product of claim 13, wherein the solar cell product is configured to receive sunlight at a first surface of the photovoltaic layer, and the nanoparticles are on an opposite side of the photovoltaic layer from the first surface.

17. The solar cell product of claim 16, including a reflector layer, wherein the nanoparticles are between the reflector layer and the photovoltaic layer.

18. The solar cell product of claim 13, wherein the nanoparticles are embedded in a dielectric material.

19. The solar cell product of claim 18, wherein the dielectric is in the form of a layer, the thickness of the dielectric layer being selected to provide near-field coupling between the nanoparticles and the photovoltaic layer.

20. The solar cell product of claim 19, wherein the thickness of the dielectric layer is about 20 nm.
